(19) United States
(12) Patent Application Publication
(10) Pub. No.: US 2013/0084147 A1
(43) Pub. Date: Apr. 4, 2013

(54) SEMICONDUCTOR WAFER TREATMENT SYSTEM

(71) Applicant: DENTON VACUUM, L.L.C., Moorestown, NJ (US)

(72) Inventors: Julius R. Abiva, Cherry Hill, NJ (US); Thomas W. Moran, JR., Newtown Square, PA (US); Paulo J. Marques, Sicklerville, NJ (US); Michael P. Nolan, Philadelphia, PA (US)

(73) Assignee: DENTON VACUUM, L.L.C., Moorestown, NJ (US)

(21) Appl. No.: 13/633,917

(22) Filed: Oct. 3, 2012

Related U.S. Application Data
(60) Provisional application No. 61/542,320, filed on Oct. 3, 2011.

(51) Int. Cl. H01L 21/677; B65G 65/00

(52) U.S. Cl. 414/217; 414/298; 414/808

(57) ABSTRACT

A wafer treatment system including a load lock chamber in communication with a process chamber. At least one cradle is provided in the load lock chamber, each cradle being adapted to receive a wafer-holding cassette. The wafers contained in the cassettes assume angularly justified positions. A multiaxial transfer unit picks up wafers from the cassettes and delivers them to the process chamber for treatment after which they are returned to the cassettes. Because all of the wafers lean in the same direction and to the same degree in their cassette slots, an end effector carried by the multiaxial transfer unit can reliably capture and release the wafers in order to consistently remove them from and place them into the cassettes.

### CROSS REFERENCE TO RELATED APPLICATION

This application claims the benefit of U.S. Provisional Application No. 61/542,320, filed Oct. 3, 2011, the disclosure of which is incorporated in its entirety by reference thereto.

### FIELD OF THE INVENTION

The present invention relates in general to semiconductor wafer treatment systems and in particular to systems including apparatus and methods for transferring wafers to and from a process chamber.

### BACKGROUND OF THE INVENTION

Semiconductor wafer treatment systems, including wafer handling systems therefor, are well known in the art. Such systems typically employ automated pickup elements for delivering unprocessed wafers to a process chamber and removing processed wafers from the process chamber. While generally effective, presently existing wafer handling systems may encounter difficulty when their pickups fail to positively grip a wafer and deliver it to the process chamber. Wafer grip failures sometimes arise from excessive gaps between the gripping members of the pickups and the faces of the wafers to be treated. The gaps frequently occur because the wafers assume inconsistent out-of-vertical positions in the cassettes in which they reside. That is to say, because of slot tolerances in the cassettes which are necessary to permit unhindered insertion of the wafers into and withdrawal of the wafers from the cassettes, some wafers may lean in one direction whereas others may lean in the opposite direction. As a consequence, the pickup element may not be able to grip certain ones of the wafers. Such grip failures can result in incomplete or improper processing of a batch of wafers, thereby resulting in less than optimum wafer treatment efficiency.

An advantage exists, therefore, for a wafer handling system including apparatus and methods for simply and reliably gripping wafers and placing them into and removing them from a processing chamber.

### SUMMARY OF THE INVENTION

The present invention provides a system including apparatus and methods for effectively treating semiconductor wafers. The apparatus includes a load lock chamber in communication with a process chamber. The load lock chamber is connected to a vacuum pump whereby a vacuum may be drawn inside the chamber as a precursor to wafer treatment in the process chamber. Accordingly to a preferred embodiment, a carousel located in the load lock chamber carries a plurality of radially directed cradles, each of which is adapted to receive a wafer-containing cassette. The cradles are sloped or canted with respect to horizontal. As a consequence, the wafers contained in the cassettes are urged by gravity to lean in a desired justified position.

A multiaxial transfer unit picks up wafers from the cassettes and delivers them to the process chamber for treatment after which they are returned to the cassettes. The multiaxial transfer unit comprises cooperating x-axis and z-axis transfer mechanisms. The z-axis transfer mechanism is inclined with respect to vertical at an angle substantially equal to the angle of slope of the cradles whereby the x-axis transfer mechanism is correspondingly sloped with respect to horizontal to extend substantially parallel to the cradles. Because all of the wafers are justified, i.e., lean in the same direction and essentially to the same degree in their cassette slots, the wafers present essentially uniformly inclined and stable surfaces that a wafer pickup element or end effector carried by the x-axis transfer mechanism can reliably capture and release in order to consistently remove and replace the wafers from and into the cassettes.

A method of wafer treatment is also provided which capitalizes on the beneficial features of the wafer handling apparatus according to the invention.

Other details, objects and advantages of the present invention will become apparent as the following description of the presently preferred embodiments and presently preferred methods of practicing the invention proceeds.

### BRIEF DESCRIPTION OF THE DRAWINGS

The invention will become more readily apparent from the following description of preferred embodiments thereof shown, by way of example only, in the accompanying drawings wherein:

FIG. 1 is a partial elevational cross-section view of a wafer treatment system according to the invention;

FIG. 2 is a right side elevational view of a load lock chamber of the system shown in FIG. 1;

FIG. 3 is an elevational view of a load lock chamber of the system shown in FIG. 1 with certain elements omitted for clarity of illustration;

FIG. 4 is a top plan view of the system shown in FIG. 1; and

FIG. 5 is perspective view of a load lock chamber of the system shown in FIG. 1 with certain elements omitted for clarity of illustration.

### DETAILED DESCRIPTION OF THE INVENTION

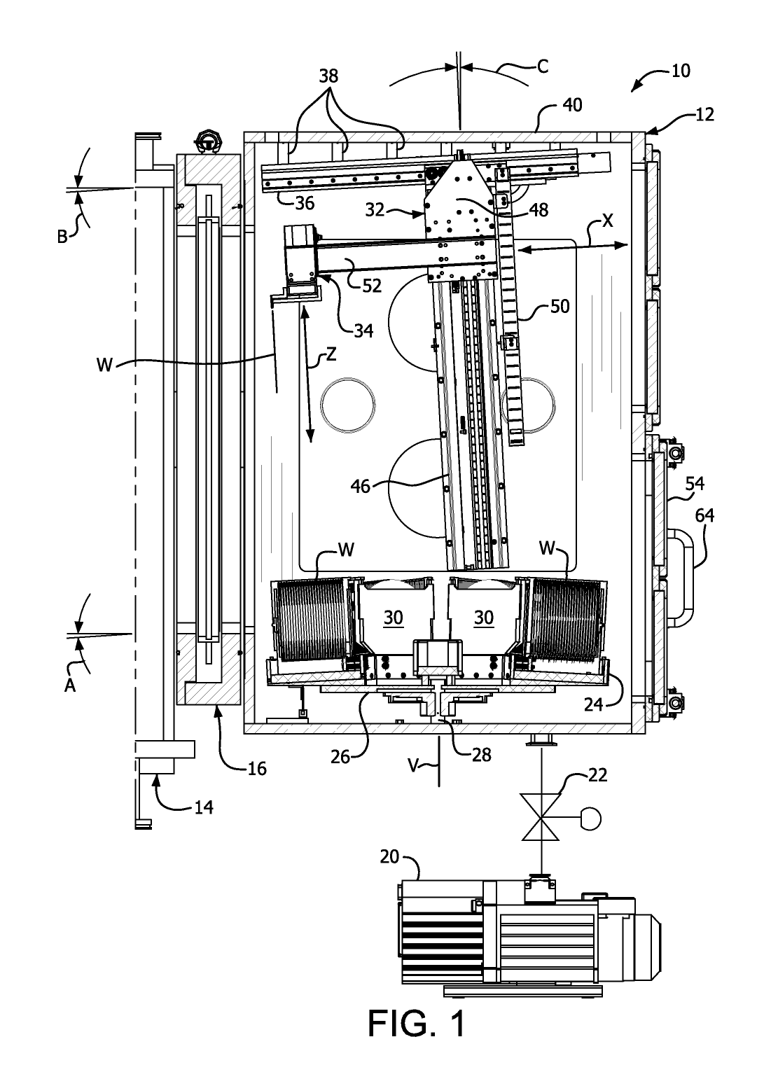

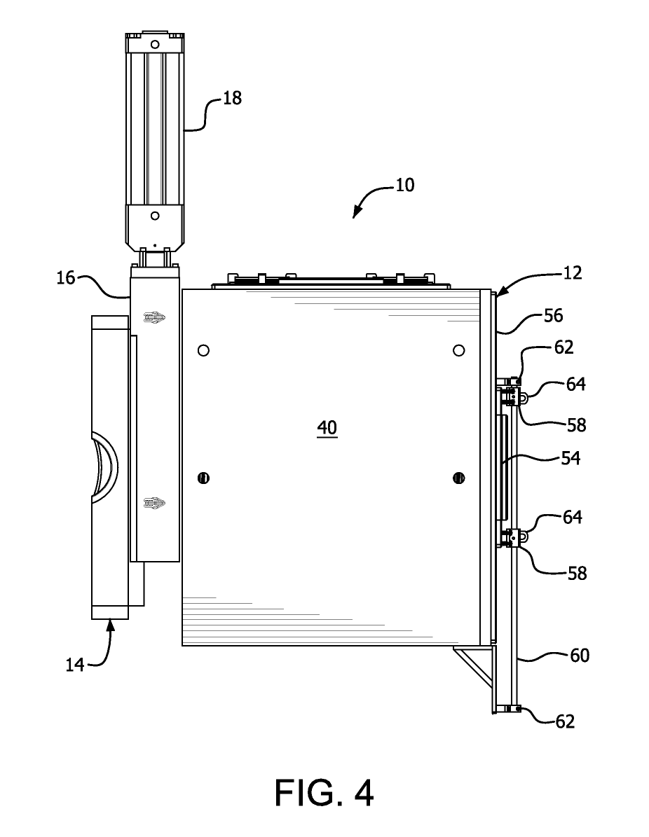

Referring to the drawings wherein like or similar references indicate like or similar elements throughout the several views, there is shown in FIGS. 1 and 4 a semiconductor wafer treatment system according to the invention identified generally by reference numeral 10, which system comprises a load lock chamber 12 and process chamber 14. Process chamber 14 may be any suitable sputtering or other semiconductor wafer treatment unit known to those skilled in the art. Accordingly, except where specified, the structural details thereof will not be described herein in detail. An isolation door or gate 16 separates the load lock chamber from the process chamber, which gate may be moved by an any suitable manual, electric, hydraulic or pneumatic linear actuator 18 (FIG. 4) in the manner known in the art. Further, as seen in FIG. 1 and as will be described in greater detail below, the load lock chamber 12 is connected to a vacuum pump 20 via a valve 22 whereby a vacuum may be drawn and sustained inside the load lock chamber in preparation for and during treatment of wafers within the process chamber 14.

Referring in particular to FIGS. 1, 3 and 5, it is seen that the load lock chamber 12 includes at least one semiconductor cassette cradle 24 which is carried by a carousel 26. According to a preferred embodiment, carousel includes a shaft 28 which is driven by an unillustrated motor to rotate about a substantially vertical axis “V”. Each cradle has a first end and a second end and is preferably radially disposed with respect to axis “V”. That is to say, each cradle has a radially inner or proximal end and a radially outer or distal end with respect to axis “V”. Six such cradles are shown in the illustrated embodiment. However, as few as one cradle may be employed to achieve the objects of the present invention. Still further, any number of cradles up to six, or even more, may be deployed on carousel 26 as may be dictated by such limitations including, for example, the spatial limitations of the load lock chamber, the size and quantity of wafers to be treated and the intended throughput of a batch of wafers to be processed in process chamber 14 during a wafer treatment procedure.

Removably received in each cradle 24 is a slotted cassette 30 which is adapted to hold a plurality of wafers “W”, e.g., twenty-five for standard cassettes, although the cassettes may hold more or less as may be desired or necessary. According to the invention, cradles 24, and thus the cassettes received therein are sloped at an acute angle “A” with respect to horizontal. Although not limited thereto, angle “A” may range from about 2°-10°, with a preferred angle being about 3°-5°. It has been observed that cradles pitched at such an angle provide wafer justification sufficient to enable reliable withdrawal of wafers from and insertion of wafers into cassettes 30 as described in greater detail below. Further, although shown as being downwardly sloped or canted from their proximal to their distal ends, it will be appreciated that the cradle slope may be reversed, i.e., the cradles may be upwardly sloped from their proximal to distal ends.

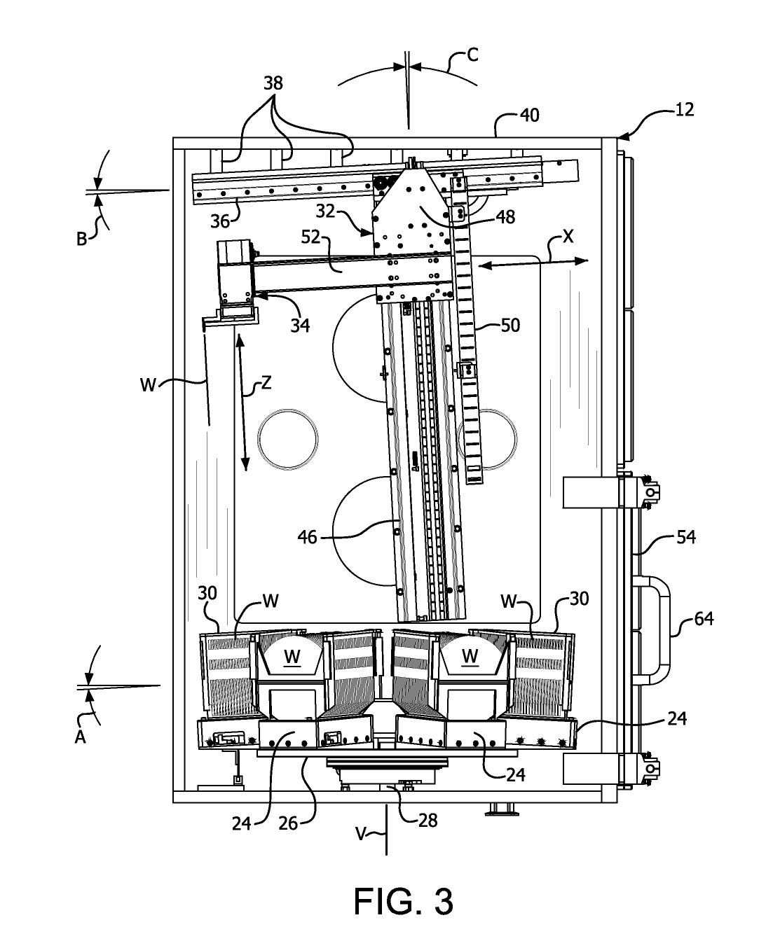

The load lock chamber 12 further includes a multiaxial Cartesian carrier or transfer unit 32 which is capable of effectuating reciprocating movement of an end effector 34, discussed below, along “X” and “Z” axes. A suitable transfer unit for this purpose may be obtained from Bell-Everman, Inc. of Goleta, Calif. Unit 32 includes a first beam 36 that is secured by spacer means 38 to a ceiling plate 40. Spacer means 38 may consist of a plurality of stub shafts as illustrated in FIGS. 1 and 3 or it may assume some other equivalent form such as one or more gussets. In any event, spacer means must secure first beam to plate 40 at an angle “B” with respect to horizontal which is preferably equal to angle “A” discussed above. While first beam 36 is shown as being disposed at a fixed angle “B”, it is conceivable that the spacer means 38 may be of an adjustable nature whereby the angle of the first beam may be adjusted relative to horizontal. Correspondingly, the cradles 24 may include means for adjusting their slopes or the slopes of the cassettes 30 received therein. In this way, the end effector 34 may effectively capture wafers from and insert wafers into cassettes that may assume varying slopes.

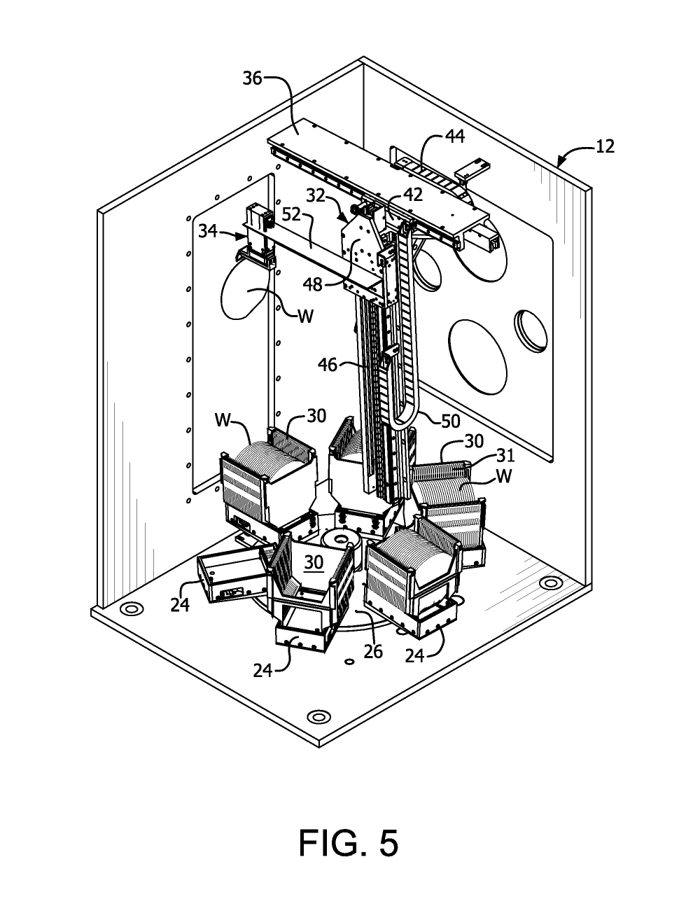

First beam 36 is a component of an x-axis transfer mechanism the structure of which is perhaps most clearly illustrated in FIG. 5. More particularly, in addition to first beam 36, the x-axis transfer mechanism further comprises a first carriage 42 that is configured for reciprocating translational movement along the first beam. First carriage 42 may be translated back and forth along the first beam by a screw jack or similar reversible drive mechanism which may for stability also include a heavy duty chain 44 or similar flexible drive member in the manner known in the art. Suspended from the first carriage 42 in a direction perpendicular to that of first beam 36 is a second beam 46. So disposed, the second beam assumes an acute angle “C” with respect to vertical that is equivalent in degree to angles “A” and “B” discussed above (see FIGS. 1 and 3). A second carriage 48 is reciprocally movable along second beam by way of a screw jack or similar reversible drive mechanism which may for stability also include a heavy duty chain 50 or similar flexible drive member.

Affixed to second carriage 48 is one end of a third beam 52 the opposite end of which carries end effector 34. Third beam 52 preferably extends perpendicular to second beam 46 and parallel to first beam 36. Many commercially available wafer-handling end effectors may be used in the present system. Accordingly, the particular structure of end effector 34 will not be described in detail as it does not form a critical part of the present invention. In any event, however, it is imperative that the chosen end effector 34 be effective for reliably capturing and releasing wafers “W” such that they may be effectively removed from and placed into the cassette slots 31 (FIG. 5). By way of example but not limitation, a suitable end effector is a Robohand electronic gripper marketed by DE-STA-CO of Auburn Hills, Mich., which has openable and closable gripper fingers that can clamp and release wafers. Whatever the end effector, its gripping members must be positioned to extend downwardly at angle which is parallel to the “Z” axis. So constructed and arranged, a wafer W may removed from and placed into a slot of an inclined cassette 30 with ease and reliability.

The operation sequence of the wafer treatment system according to the invention is generally as follows.

The load lock chamber 12 is vented to atmospheric pressure by placing valve 22 into a venting position. Preferably concurrently therewith, the x-axis and z-axis transfer mechanisms are moved to a home position wherein the end effector 34 is clear of any possible obstructions.

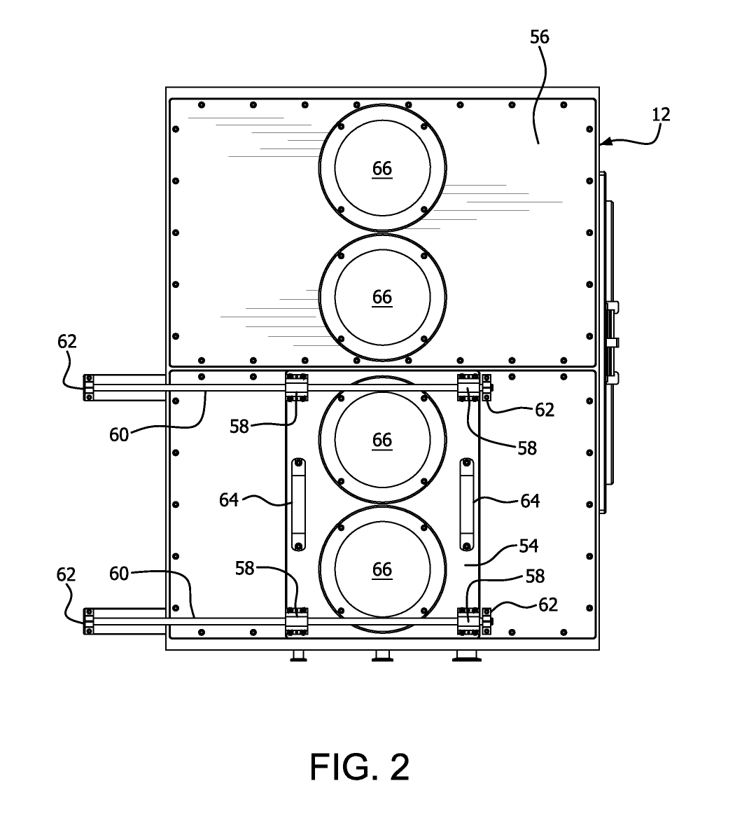

Once the load lock chamber is vented to the atmosphere, a load lock chamber access door 54 (FIGS. 1-4) may be opened. According to a preferred embodiment, access door 54 is slidably mounted on a side wall 56 of load lock chamber 12 opposite process chamber 14. Toward that end, access door 54 may have affixed thereto rail-receiving members 58 (FIGS. 2 and 4) adapted to slidingly receive a pair of guide rails 60, which rails are fixedly mounted at their opposite ends to anchorages 62 that are secured to load lock chamber 12. At least one or, more preferably, two handles 64 are attached to access door 54 to facilitate its movement along rails 60. FIGS. 2 and 4 depict the access door in the closed position. In order for a worker to access the interior of the load lock chamber, he/she must grasp handle(s) 64 and pull access door 54 along the rails 60 a distance sufficient to accommodate insertion and removal of cassettes 30 from cradles 24. While described in the preferred embodiment as being a slidable door, it will be understood that access door may be pivotally mounted to side wall 56 of load lock chamber in the manner of a hatch. Additionally, side wall 56 as well as other side walls of the load lock chamber may be fitted with one or more portal windows 66 (FIG. 2) whereby a worker may observe the workings of the multiaxial transfer unit 32 and end effector 34 during placement of wafers into and removal of wafers from process chamber 14.

Once the load lock chamber 12 is vented to atmosphere and the access door 54 is opened, a worker may begin to place wafers into the load lock chamber. More specifically, a slotted cassette 30 containing one or more wafers “W” is placed into a first sloped cradle 24. Once the first cradle is loaded with a cassette, the carousel 26 is rotated by a worker-initiated operation or by an automated command a sufficient angular distance to bring a second cradle into alignment with the access door opening whereby a second wafer-carrying cassette may be loaded into the next cradle. This process is repeated as necessary to load a desired batch of wafers into the load lock chamber 12 for processing by process chamber 14.

After the desired number of cassettes are loaded into the load lock chamber, access door 54 is closed, the valve 22 is placed into a vacuum position and vacuum pump 20 is activated to draw a vacuum within the load lock chamber. Upon reaching the desired reduced pressure interiorly of the load lock chamber, typically about 50-150 millitorr, the isolation gate 16 between the load lock and process chambers is opened. Thereafter, the carousel 26 is homed, either by the worker or automatically, the carousel is rotated again to bring a first loaded cassette 30 into a process chamber loading position and the x-axis and z-axis transfer mechanisms of the multiaxial transfer unit 32 move the end effector 34 into a waiting position in alignment with a wafer on the waiting cassette. The z-axis transfer mechanism is then activated to lower the end effector to a position whereby it can grab or capture a wafer. Once in proper vertical position, the end effector is activated to grab the wafer. Upon capturing of the wafer by the end effector, the z-axis transfer mechanism is activated to raise the wafer to an elevation suitable for insertion into the process chamber 14. Once at the proper insertion elevation, the x-axis transfer mechanism is activated to insert the wafer into the process chamber. Following this, the z-axis transfer mechanism is activated to lower the wafer into a slot of an awaiting receptacle located inside the process chamber 14. In this regard, and although not shown, the awaiting wafer-receiving receptacle in the process chamber includes slots likewise angled with respect to vertical at an angle substantially equal to angle “C” such that the wafers are angularly justified therein and may be readily and reliably removed therefrom once wafer processing is completed. Upon placement of the wafer into the receptacle in process chamber 14, the end effector releases the wafer, the z-axis transfer mechanism raises the end effector, and the x-axis transfer mechanism retracts the end effector into the load lock chamber whereby it assumes a ready position above the next wafer to be treated. The foregoing procedure, which is preferably fully automated, continues until the first cassette in the load lock chamber is unloaded and its counterpart receptacle in the process chamber is loaded.

Upon depletion of a first cassette 30 of its wafer supply, the carousel is rotated to an extent that a second cassette is brought into position beneath the end effector. Simultaneously, another receptacle is brought into wafer receiving position within process chamber 14. Once both the second cassette and the second receptacle are in their appropriate positions, the foregoing cassette unloading and process chamber receptacle filling process begins anew and proceeds until unloading of the second cassette is completed. It will be appreciated that all of the unloading and filling steps are repeated until all cassettes in the load lock chamber are emptied of their wafers and such wafers are placed into corresponding receptacles in the process chamber.

Once all wafers in a batch are loaded into the process chamber, the isolation gate 16 is closed and processing of the wafers within process chamber 14 begins. Upon completion of wafer processing, the isolation gate 16 is opened and the entire loading process described above is reversed. That is to say, coated wafers are removed one-by one from the process chamber receptacles and placed into corresponding cassettes 30 in load lock chamber 12. Once unloading of the wafers from the processing chamber is finished, the isolation gate 16 is again closed and the valve 22 is placed into venting position whereby the load lock chamber is again vented to atmospheric pressure. And, once the load lock chamber has achieved atmospheric pressure, access door 54 and cassettes 30 containing processed wafers are sequentially removed from their cradles until all cassettes are removed whereby the entire process described above may begin again.

Although the invention has been described in detail for the purpose of illustration, it is to be understood that such detail is solely for that purpose and that variations can be made therein by those skilled in the art without departing from the spirit and scope of the invention as claimed herein.

For example, while shown as being rotatable about a vertical axis “V”, it will be understood that carousel 26 may rotate about axes of other angular orientations up to and including a horizontal axis. In any event, however, the cradles 26 must be sloped or inclined in one direction or another in order to achieve effective justification of wafers “W” such that they may be reliably captured by the inclined gripping fingers of end effector 34. In addition, while a carousel is the preferred mode of supporting cradle(s) 24, it is also contemplated that the cradle(s) may be carried by a reciprocating platform or the like, whereby one or more cradles may be brought into a position in alignment with the end effector 34.

In addition, while the present invention has been disclosed with respect to sloped/inclined cradles and cassettes, it will be understood that a comparable effect may be achieved by using horizontally oriented cradles with cassettes having slots inclined with respect to vertical at an acute angle substantially equal to angle “C” discussed above.

What is claimed is:

1. Wafer handling apparatus comprising:
at least one sloped cassette having a first end and a second end; and
means for removing wafers from and placing wafers into said at least one cassette.

2. The apparatus of claim 1 further comprising a carousel, said at least one cassette being carried by said carousel.

3. The apparatus of claim 2 wherein said first end is a radially proximal end and said second end is a radially distal end.

4. The apparatus of claim 3 wherein said at least one cassette slopes downwardly from said radially proximal end to said radially distal end.

5. The apparatus of claim 2 wherein said carousel rotates about a substantially vertical rotation axis.

6. The apparatus of claim 1 wherein said means for removing and placing wafers comprises a multiaxial transfer unit including x-axis and z-axis transfer mechanisms and means for holding wafers.

7. The apparatus of claim 6 wherein said x-axis transfer mechanism is disposed at an angle corresponding to the slope of said at least one cassette.

8. Wafer handling apparatus comprising:
at least one sloped cradle having a first end and a second end;
at least one cassette received in said at least one cradle; and
means for removing wafers from and placing wafers into said at least one cassette.

9. The apparatus of claim 8 further comprising a carousel, said at least one cradle being carried by said carousel.

10. The apparatus of claim 9 wherein said first end is a radially proximal end and said second end is a radially distal end.

11. The apparatus of claim 10 wherein said at least one cradle slopes downwardly from said radially proximal end to said radially distal end.

12. The apparatus of claim 8 wherein said carousel rotates about a substantially vertical rotation axis.

13. The apparatus of claim 8 wherein said at least one cassette is removably received in said at least one cradle.

14. The apparatus of claim 8 wherein said means for removing and placing wafers comprises a multiaxial transfer unit including x-axis and z-axis transfer mechanisms and means for holding wafers.

15. The apparatus of claim 14 wherein said x-axis transfer mechanism is disposed at an angle corresponding to the slope of said at least one cradle.

16. Wafer handling apparatus comprising:
at least one cassette having a plurality of slots disposed at an acute angle with respect to vertical; and
means for removing wafers from and placing wafers into said at least one cassette.

17. The apparatus of claim 16 further comprising a carousel, said at least one cassette being carried by said carousel.

18. The apparatus of claim 17 wherein said carousel rotates about a substantially vertical rotation axis.

19. The apparatus of claim 16 wherein said means for removing and placing wafers comprises a multiaxial transfer unit including x-axis and z-axis transfer mechanisms and means for holding wafers.

20. The apparatus of claim 19 wherein said x-axis transfer mechanism is disposed at an angle corresponding to the angle of said slots.

21. A wafer treatment system comprising:
a wafer process chamber; and
a load lock chamber including a wafer handling apparatus comprising:
at least one cassette having a plurality of slots disposed at an acute angle with respect to vertical; and
means for (a) removing wafers from said at least one cassette, (b) placing wafers into said wafer process chamber, (c) removing processed wafers from said wafer process chamber, and (d) placing processed wafers into said at least one cassette.

22. The system of claim 21 further comprising a carousel, said at least one cassette being carried by said carousel.

23. The system of claim 22 wherein said carousel rotates about a substantially vertical rotation axis.

24. The system of claim 21 further comprising means for drawing a vacuum in said load lock chamber.

25. The system of claim 21 wherein said means for removing and placing wafers comprises a multiaxial transfer unit including x-axis and z-axis transfer mechanisms and means for holding wafers.

26. The system of claim 25 wherein said x-axis transfer mechanism is disposed at an angle corresponding to the slope of said slots.

27. A semiconductor wafer treatment method comprising:
removing a wafer from a sloped slot;
processing the wafer; and
placing the processed wafer into the slot.

28. The method of claim 27 wherein said sloped slot is inclined at an acute angle with respect to vertical.
